(19) United States
(12) Patent Application Publication
(10) Pub. No.: US 2025/0125284 A1
(43) Pub. Date: Apr. 17, 2025

(54) ARC PREVENTION FOR BONDED WAFERS OF A CHIP STACK

(71) Applicant: SEMICONDUCTOR COMPONENTS INDUSTRIES, LLC, Scottsdale, AZ (US)

(72) Inventors: Jeffrey Peter GAMBINO, Gresham, OR (US); David T. PRICE, Gresham, OR (US); Marc Allen SULFRIDGE, Boise, ID (US); Richard MAURITZSON, Meridian, ID (US); James Joseph STEFFES, Poughkeepsie, NY (US)

(73) Assignee: SEMICONDUCTOR COMPONENTS INDUSTRIES, LLC, Scottsdale, AZ (US)

(21) Appl. No.: 18/488,628

(22) Filed: Oct. 17, 2023

(51) Int. Cl. H01L 23/60; H01L 23/00; H01L 27/146

(52) U.S. Cl. CPC H01L 23/60; H01L 24/05; H01L 24/08; H10F 39/018; H10F 39/026; H10F 39/8057; H10F 39/809; H01L 24/06; H01L 2224/05567; H01L 2224/05624; H01L 2224/05644; H01L 2224/05647; H01L 2224/05655; H01L 2224/06102; H01L 2224/08145

(57) ABSTRACT

A semiconductor device may include a first chip with a first wafer and a first dielectric layer, and a second chip that includes a second wafer and a second dielectric layer, the second chip having a backside surface and a frontside surface opposed to the backside surface and bonded to the first chip at the frontside surface to define a bond line between the first dielectric layer and the second dielectric layer. The semiconductor device may include a die seal layer on the backside surface having a die seal ground contact in contact with the second wafer, and an electrostatic discharge path that includes the die seal layer, the die seal ground contact, a first die seal in the first dielectric layer, a second die seal in the second dielectric layer, and a hybrid bond connecting the first die seal and the second die seal through the bond line.

### TECHNICAL FIELD

This description relates to chip stacking.

### BACKGROUND

Examples of chip stacks include structures in which one chip (also referred to as a top chip, or a second chip) is flipped and bonded to another chip (also referred to as a bottom chip, or a first chip). Put another way, a frontside of the top chip may be bonded to a frontside of the bottom chip, so that a backside of the top chip and the backside of the bottom chip are available for electrical connections and other functions.

For example, when the top chip is an optical sensor chip, optical sensing elements may be disposed on or close to the backside of the top chip, so that light that is incident on the exposed backside of the top chip may easily reach optical sensing elements. More generally, such chip stacking techniques make it possible to form reliable, low-latency connections between circuits/devices of the stacked chips.

Such stacked chips often include insulating materials, such as oxides, disposed between a bottom wafer material of the bottom chip and a top wafer material of the top chip. Such oxides may be used to bond the bottom and top chips to one another and enable electrical connections therebetween, such as when implementing copper (Cu) hybrid bonds.

### SUMMARY

Components of a chip stack may be configured to provide an electrostatic discharge path and prevent arcing events.

According to one general aspect, a semiconductor device includes a first chip that includes a first wafer and a first dielectric layer disposed thereon, and a second chip that includes a second wafer and a second dielectric layer disposed thereon, the second chip having a backside surface and a frontside surface opposed to the backside surface, the second chip being bonded to the first chip at the frontside surface to define a bond line between the first dielectric layer and the second dielectric layer. The semiconductor device includes an opening through the backside surface of the second chip that extends into the second dielectric layer, and a bond pad disposed within the second dielectric layer between the second wafer and the bond line, and extending beyond the opening in a direction parallel to the bond line.

According to another general aspect, a semiconductor device includes a first chip that includes a first wafer and a first dielectric layer disposed thereon, and a second chip that includes a second wafer and a second dielectric layer disposed thereon, with a bond pad disposed within the second dielectric layer, the second chip having a backside surface and a frontside surface opposed to the backside surface and being bonded to the first chip at the frontside surface to define a bond line between the first dielectric layer and the second dielectric layer. The semiconductor device also includes an opening through the backside surface of the second chip and through the second wafer, the opening extending into the second dielectric layer to expose only a portion of an upper surface of the bond pad for electrical connection thereto.

According to another general aspect, a method of making a semiconductor device includes forming a first chip that includes a first wafer and a first dielectric layer disposed thereon, forming a second dielectric layer on a second wafer of a second chip, and forming a bond pad within the second dielectric layer. The method further includes bonding a frontside surface of the second chip to the first chip to define a bond line between the first dielectric layer and the second dielectric layer, and etching an opening through a backside surface of the second chip that extends through the second wafer and into the second dielectric layer to the bond pad, for electrical connection thereto.

The details of one or more implementations are set forth in the accompanying drawings and the description below. Other features will be apparent from the description and drawings, and from the claims.

### BRIEF DESCRIPTION OF THE DRAWINGS

FIG. 1 is a block diagram of a chip stack with arc prevention.

FIG. 2 is a top view of an example implementation of the chip stack of FIG. 1.

FIG. 3 illustrates a first cross-section of a first example implementation of the chip stack of FIGS. 1 and 2.

FIG. 4 illustrates a second cross-section of the first example implementation of the chip stack of FIGS. 1 and 2.

FIG. 5A illustrates a first example operation for manufacturing a second example implementation of the chip stack of FIG. 1.

FIG. 5B illustrates a second example operation for manufacturing the second example implementation of the chip stack of FIG. 5A.

FIG. 5C illustrates a third example operation for manufacturing the second example implementation of the chip stack of FIGS. 5A and 5B.

FIG. 5D illustrates a fourth example operation for manufacturing the second example implementation of the chip stack of FIGS. 5A-5C.

FIG. 6A illustrates a first example operation for manufacturing a third example implementation of the chip stack of FIG. 1.

FIG. 6B illustrates a second example operation for manufacturing the third example implementation of the chip stack of FIG. 6A.

FIG. 6C illustrates a third example operation for manufacturing the third example implementation of the chip stack of FIGS. 6A and 6B.

FIG. 6D illustrates a fourth example operation for manufacturing the third example implementation of the chip stack of FIGS. 6A-6C.

FIG. 7 illustrates a fourth example implementation of the chip stack of FIG. 1.

FIG. 8 is a flowchart illustrating example operations for manufacturing the chip stack of FIG. 1.

### DETAILED DESCRIPTION

Conventional chip stacks are subject to electrostatic discharge events, such as may occur during various manufacturing processes, including plasma etching or plasma deposition. Such electrostatic discharge events may result in damage to elements of the chip stack, and associated losses of time and resources.

For example, as noted above, chip stacks often include a top dielectric of a top wafer bonded to a bottom dielectric of a bottom wafer. For example, a top oxide may be bonded to a bottom oxide. As insulating materials, such dielectrics do not provide sufficient discharge paths for electrostatic discharge.

It is possible to provide additional doping of the top wafer to facilitate electrostatic discharge. However, such additional doping may be required to be added during frontside processing of the top chip and prior to bonding of the top chip to the bottom chip, in order to avoid damage to elements of the active circuits, e.g., during subsequent activation of such doping. As a result, it may be difficult or impossible to add sufficient doping near a backside (top) of the top chip, where the doping would be most advantageous in facilitating electrostatic discharge.

It is also possible to provide an electrostatic discharge path through metal contact layers and/or other conductive elements associated with the active circuits of a chip stack, and via one or more Cu hybrid bonds between the bottom dielectric layer and the top dielectric layer. However, a layout of, and available wafer area for, such metal elements may be dictated by the size, functions, and connections of the active circuits, and may be suboptimal for purposes of electrostatic discharge (e.g., may not provide a sufficiently straight path to ground). In addition, even when present, an efficacy of such an electrostatic discharge path may be limited by an ability of the top wafer to contribute to a path to ground, as referenced above.

Chip stacks may include a die seal structure, or die seal, designed to prevent moisture ingress from outside the chip stack. For example, conventional chip stacks may be susceptible to failure or malfunction resulting from moisture ingress. In particular, it is possible for moisture to diffuse into the chip stack and cause corrosion of bonds at a bond line at which the top chip is joined to the bottom chip.

To reduce moisture ingress, a die seal may include connected die seal layers within each of the bottom dielectric and the top dielectric. Such a die seal structure may extend around a periphery of the chip stack, to minimize moisture intrusion and associated damage to the chip stack.

Described techniques define an electrostatic discharge path that includes a die seal structure with discrete or non-continuous hybrid bonds. Such an electrostatic discharge path may be defined to provide a straight and effective path to ground, regardless of where charge buildup occurs within the chip stack. Moreover, described techniques ensure reliable bonding between the top and bottom dielectric layers, while still providing the types of moisture protection referenced above. Additionally, as the described die seal structure is at a periphery of a chip stack, the die seal structure does not interfere with, or disrupt, operations of any active circuits of the chip stack.

In some implementations, the described die seal structure may be connected to a metal element associated with, or in a vicinity of, the active circuits, such as a light shield. For example, a die seal layer of the die seal structure may be connected to the light shield. Consequently, charge buildup associated with such a metal element(s) (e.g., light shield) may also be effectively discharged using the described die seal structure.

Further, additional processing of the top wafer may be performed to enhance operations of the electrostatic discharge path. For example, additional doping of the top wafer referenced above may be provided. Additionally, or alternatively, trenches may be added within the top wafer, where such trenches, and associated trench doping and/or trench fill material, may facilitate desired electrostatic discharge(s).

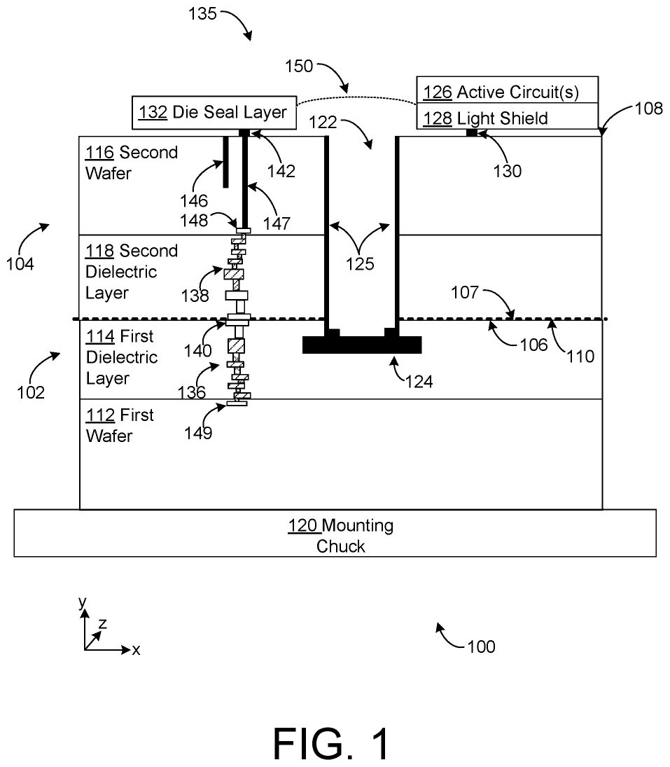

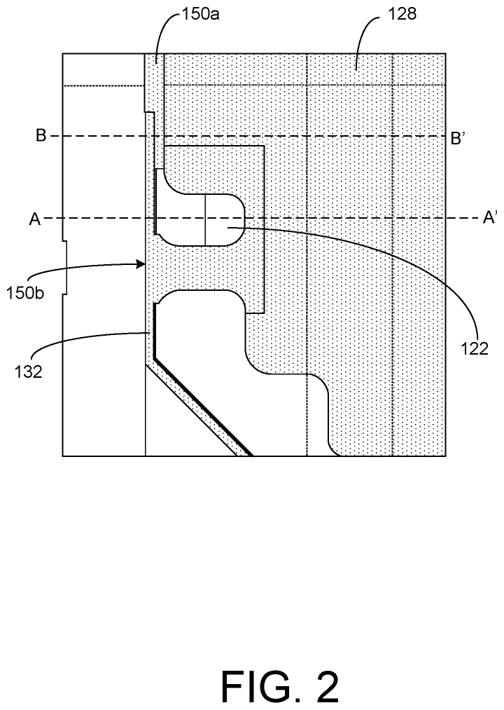

FIG. 1 is a block diagram of a chip stack 100 with arc prevention. It will be appreciated that FIG. 1, as well as FIGS. 2-7, are simplified examples intended for illustration and explanation of various aspects described with respect to the chip stack 100. Many aspects, features, and components of the chip stack 100, and variations thereof, are omitted from FIG. 1 for purposes of clarity and conciseness. Moreover, neither FIG. 1, nor any of FIGS. 2-7, should be understood to be necessarily drawn to scale.

As referenced above, and illustrated in FIG. 1, the chip stack 100 includes a first chip 102, which may also be referred to as a primary chip or a bottom chip. The first chip 102 may represent, e.g., an ASIC chip, an image sensor processor (ISP) chip, or an integrated passive chip (IPC), or any digital processing chip.

A second chip 104 may be disposed on the first chip 102. For example, the second chip 104 may include an optical sensor chip, including, e.g., an image sensor chip, such as a complementary metal oxide semiconductor (CMOS) chip.

As shown, a frontside surface 106 of the first (bottom) chip 102, shown as an upper surface in FIG. 1, may be face-to-face with a frontside surface 107 of the second (top) chip 104. A backside surface 108 of the second chip 104, shown facing an upwards direction in FIG. 1, may be faced away from the first chip 102 and opposed to the frontside surface 106. Thus, the second chip 104 is above the first chip 102 in a y direction, and joined (e.g., bonded) to the first chip 102 along an x-z plane to define a bond line 110.

As further illustrated, the first chip 102 includes a first wafer 112 and a first dielectric layer 114. Similarly, the second chip 104 includes a second wafer 116 and a second dielectric layer 118. For example, the first wafer 112 and the second wafer 116 may be formed using Silicon (Si). The dielectric layers 114, 118 may each include multiple dielectric layers, as illustrated in various examples, below. For example, such dielectric layers may include various types of Silicon nitride (SiN) or Silicon dioxide (SiO₂).

The first chip 102 and the second chip 104 may have various types of circuits formed therein. Such circuits may be formed in or on any of the first wafer 112, first dielectric layer 114, second wafer 116, and/or second dielectric layer 118. For example, when the second chip 104 includes an image sensor chip, provided image sensors may include a pixel array used to produce color images by forming a color filter array (CFA) and associated microlenses over the pixel array. For example, complementary metal-oxide-semiconductor (CMOS) image sensors may include or utilize photodiodes, related circuitry, dielectric layers, and metal interconnects, all formed on a substrate to provide an image sensor chip. The second chip 104 may include any type of image sensor chip and the first chip 102 may include any circuit chip configured to operate and/or receive an output of such an image sensor chip. Additional or alternative details and examples of these and related image sensor circuits are provided below.

The chip stack 100 in FIG. 1 is pictured as being positioned on a mounting chuck 120, which may occur during a manufacturing process(es) of the chip stack 100. In addition to providing mechanical support for the chip stack 100, the mounting chuck 120 provides an electrical ground, which may be used to prevent damage from arcing events that result from discharge of charge buildups.

For example, in FIG. 1, an etched opening 122 provides access to a metal (e.g., Aluminum) bond pad 124. Walls of the opening are covered with a passivation material 125. The etched opening 122 may provide access to the bond pad 124 for purposes of providing an electrical connection, such as a connection to external circuits. For example, in subsequent operations, the chip stack 100 may be removed from the mounting chuck and attached to a substrate that supports external circuits, which may be attached to the bond pad 124 using the opening 122.

During etching of the opening 122, e.g., during plasma etching, charge buildup may occur at various metal elements while the electric field used for the etching is present. As referenced above, conventional chip stacks do not provide adequate discharge paths for such charge buildups to the ground potential of the mounting chuck 120, so that arcing events may occur that cause damage to the second wafer 116 or other elements of the chip stack 100.

For example, various active circuits 126 may be positioned in or on the backside surface of the second wafer 116, such as a color filter array and microlens array. The active circuits 126 may include or utilize a light shield 128, including a metal light shield, such as a Tungsten (W) light shield. More generally, various antireflective materials to facilitate image sensing operations, as well as other elements not shown in the simplified example of FIG. 1, such as trench isolation structures for electrical and/or light isolation purposes, and metal layers used to connect the active circuits 126 to the first chip 102. Also, other dielectric materials may be included on the backside surface 108, which are not shown in FIG. 1 for the sake of simplicity.

As the light shield 128 is made of metal in the example of FIG. 1, the types of charge buildup referenced above may occur in the light shield 128. A ground contact 130 that connects the light shield 128 to the second wafer 116 may be included, where the ground contact 130 may be intended to facilitate electrostatic discharge to the ground potential of the mounting chuck 120. The ground contact 130 may be positioned within a via formed through an intervening dielectric (not explicitly illustrated in the simplified example of FIG. 1). This ground contact 130 may sometimes be referred to as a “light shield ground contact.”

As noted above, intervening portions of the second wafer 116, the second dielectric layer 118, the first dielectric layer 114, and the first wafer 112, as well as any metal elements or layers included therein, may be insufficient or suboptimal with respect to providing a grounding connection to the mounting chuck 120. In addition, other metal layers or metal elements may be present, including, e.g., a metal layer illustrated in FIG. 1 as a die seal layer 132. Therefore, charge buildup may occur at such additional metal elements as well, which may also result in arcing damage, e.g., during plasma etching of the opening 122.

In order to prevent such arcing damage, the chip stack 100 of FIG. 1 includes an electrostatic discharge path 135, which provides a suitable path to the ground potential of the mounting chuck 120. For example, the electrostatic discharge path 135 includes a first die seal 136 in the first dielectric layer 114, a second die seal 138 in the second dielectric layer 118, and a hybrid bond 140 that connects the first die seal 136 and the second die seal 138 at the bond line 110.

The hybrid bond 140, and other hybrid bonds described herein, generally allows for electrical connections to be formed and forms a mechanically stable structure between the two wafers 112, 116. In some implementations, hybrid bond pads of the hybrid bond 140 may be metal, such as copper, nickel, gold, or other suitable metals known in the art. In other implementations, the hybrid bond pads may be made of other non-metal conductive material. A hybrid bond may also be referred to as a direct bond interconnect (DBI).

The hybrid bond 140 is illustrated in cross-section in the example of FIG. 1, and may not be present in other cross sections of the chip stack 100. In other words, the hybrid bond 140 may represent a discrete or non-continuous hybrid bond, which may be positioned at desired intervals under the die seal layer 132. As a result, sufficient numbers of the hybrid bond 140 may be included to facilitate desired levels of electrostatic discharge, while still utilizing oxide-oxide bonding between the first dielectric layer 114 and the second dielectric layer 118 at the bond line 110 to provide secure and reliable formation of the chip stack 100, while avoiding bonding voids.

The electrostatic discharge path 135 may include various other elements and aspects that facilitate sufficient electrostatic discharge through the second wafer 116, the second dielectric layer 118, the first dielectric layer 114, and the first wafer 112. In particular, the second wafer 116, by itself, may not provide sufficient or desired levels of conductivity between the die seal layer 132 and the second die seal 138 for potential levels of electrostatic discharge. In FIG. 1, one or more elements may therefore be added to the second wafer 116 under the die seal layer 132 to facilitate such desired levels of conductivity between the die seal layer 132 and the second die seal 138 (and thereby to the hybrid bond 140 and the first die seal 136).

For example, a ground contact 142 may connect the die seal layer 132 to the second wafer 116. Similar to the ground contact 130, the ground contact 142 may be positioned within a via formed through an intervening dielectric (not explicitly illustrated in the simplified example of FIG. 1).

A deep trench 146 may be provided that extends from the backside surface 108 towards the second dielectric layer 118. As described in more detail, below, the deep trench 146 may be filled with an insulating material, and an outer perimeter of the deep trench may be provided with a doped layer that enhances conductivity for electrostatic discharge from the die seal layer 132 along the electrostatic discharge path 135.

In other example implementations, a conductive deep trench extending from the backside surface 108 towards the second dielectric layer 118 may be included in addition to or in the alternative to the deep trench 146. As shown in FIG. 1, a conductive deep trench 147 may extend from the ground contact 142 to the second die seal 138. More particularly, the conductive deep trench may be filled with a conductive material, such as a metal or Polysilicon, to enhance conduction between the ground contact 142 and the second die seal 138.

In the example of FIG. 1, the conductive deep trench 147 may be connected to a doped layer 148 of the second die seal 138. For example, the doped layer 148 may be provided with additional doping to facilitate conduction along the electrostatic discharge path 135. A similar doped layer 149 may be provided as part of the first die seal 136, and be positioned near a border of the first dielectric layer 114 and the first wafer 112.

In the simplified example of FIG. 1, the deep trench 146 and the conductive deep trench 147 are illustrated, with the deep trench 146 being positioned laterally away from the ground contact 142. In other examples, however, the conductive deep trench may be omitted, in which case the deep trench 146 may be positioned in contact with the ground contact 142. Further in such implementations, two or more deep trenches (similar to the deep trench 146) may be included, at least one of which may be in contact with the ground contact 142. In still other examples, the deep trench 146 may be omitted, and the conductive deep trench 147 may be included, or both of the deep trench 146 and the conductive deep trench 147 may be omitted.

In a final example of FIG. 1, a shield connection 150 may be added that electrically connects the light shield 128 and the die seal layer 132. The shield connection 150 is shown as a dashed line in FIG. 1 to indicate that the shield connection 150 is not visible in the cross-section of FIG. 1, but is positioned to connect the light shield 128 and the die seal layer 132 outside of a perimeter of the opening 122.

FIG. 2 illustrates a partial top view of an example implementation of the chip stack 100 of FIG. 1. In the example of FIG. 2, the die seal layer 132 and the light shield 128 are illustrated, along with the opening 122. The shield connection 150 is illustrated as including a first shield connection 150a on a first side of the opening 122 and a second shield connection 150b on a second side of the opening 122.

FIG. 2 illustrates that the die seal layer 132 may be positioned at an edge or perimeter of the chip stack 100. In the particular example of FIG. 2, a portion of the die seal layer 132 is illustrated in a vicinity of a corner of the chip stack 100, and includes an angled portion that is not directly connected to the light shield 128. In some implementations, the die seal layer 132 may be used for alignment purposes, e.g., when singulating the chip stack 100. Thus, more generally, the die seal layer 132 may be positioned relative to the chip stack 100, and connected to the light shield 128 using the shield connection 150, at any convenient or available location along the backside surface 108 of the chip stack 100.

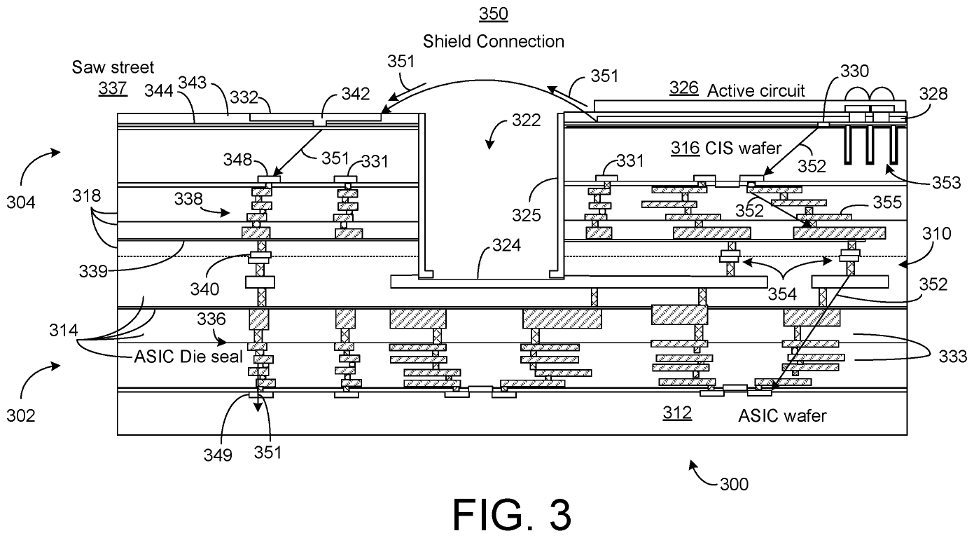

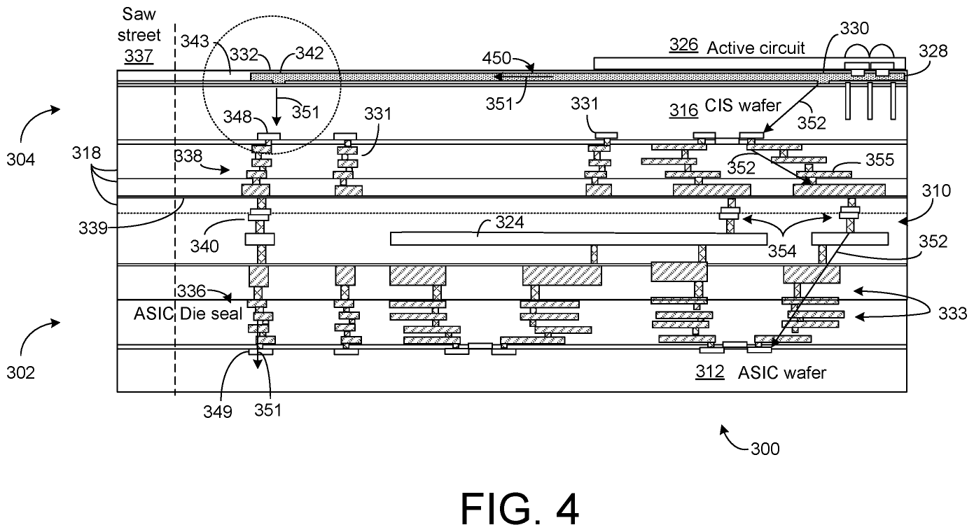

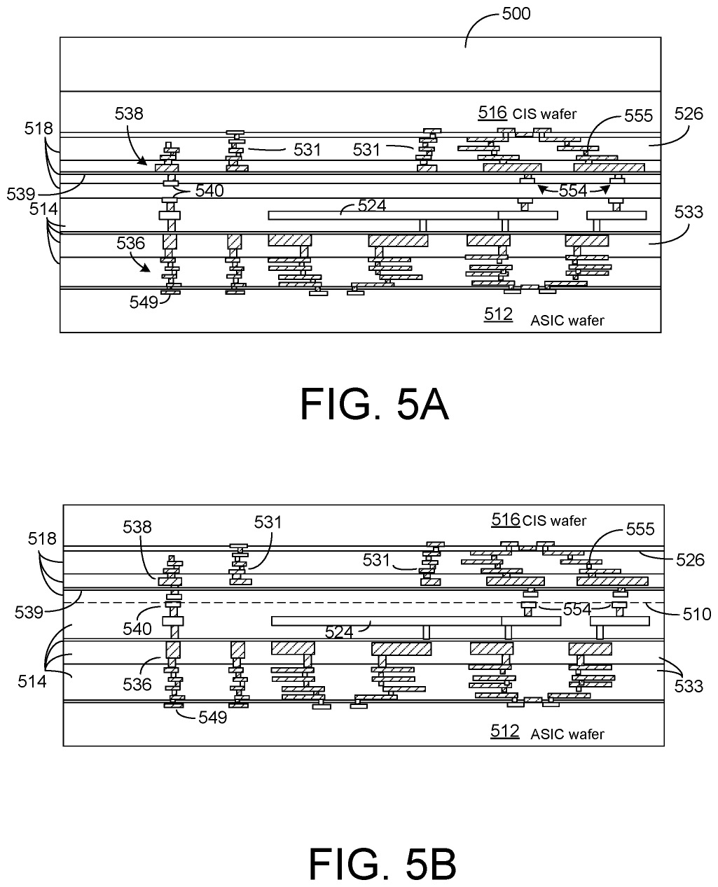

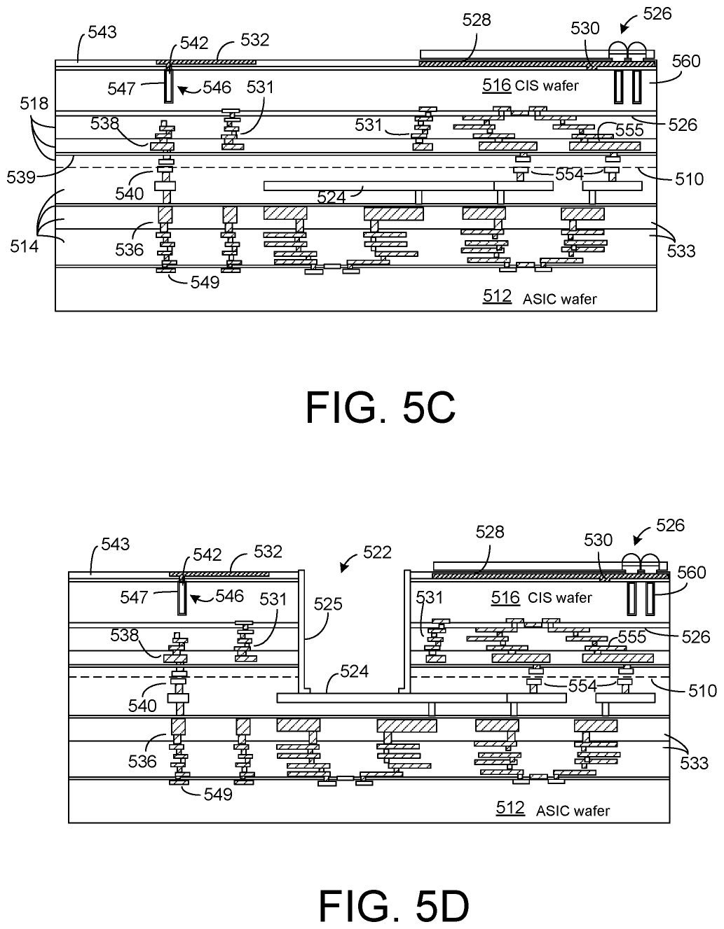

FIG. 3 illustrates a first cross-section of a first example implementation of the chip stack of FIGS. 1 and 2, taken along line A-A′ of FIG. 2. FIG. 4 illustrates a second cross-section of the first example implementation of the chip stack of FIGS. 1 and 2, taken along line B-B′ of FIG. 2. In the following examples of FIGS. 3 and 4, as well as in FIGS. 5A-5D, 6A-6D, and 7, a number of common or like elements are included, many of which correspond to, or provide examples of, previously-discussed elements of FIGS. 1 and 2. Such elements are numbered to correspond to the numbering scheme of FIG. 1, for the sake of clarity and consistency.

For example, in an example chip stack 300 of FIG. 3, an ASIC chip 302 provides an example of the first chip 102 of FIG. 1, and an ASIC wafer 312 and first dielectric layer(s) 314 provide examples of the first wafer 112 and the first dielectric layer 114 of FIG. 1, respectively. As referenced above, and shown in FIG. 3, the first dielectric layer 314 includes a number of different dielectric materials/layers, which are not described here in further detail.

Further in FIG. 3, a contact image sensor (CIS) chip 304 provides an example of the second chip 104 of FIG. 1, and a CIS wafer 316 and second dielectric layer(s) 318 provide examples of the second wafer 116 and the second dielectric layer 118, respectively. As just referenced with respect to the first dielectric layer 314, the second dielectric layer 318 includes a number of different dielectric materials/layers. As referenced above, and described in more detail, below, the second dielectric layer(s) 318 may include one or more oxide layers, and one or more SiN layers 339, or other dielectric material(s).

Consistent with the example of FIG. 1, the chip stack 300 of FIG. 3 includes a bond line 310 at which the first chip 302 and the CIS chip 304 are bonded. A bond pad 324 is accessible by way of an etched opening 322. The opening 322 is lined with passivation layer 325.

As shown in FIG. 3, the bond pad 324 extends beyond the opening 322 in a direction parallel to the bond line 310. A seal ring 331 is shown in cross-section and extends around the opening 322. The seal ring 331 extends around a perimeter of the opening 322. For example, the seal ring 331 may be formed using a suitable metal or other moisture resistant material, such as, e.g., Tungsten, polysilicon, or combinations thereof.

As is typical in chip stack devices, the ASIC chip 302 may be connected and configured to control various operations of the CIS chip 304. For example, the ASIC wafer 312 may include various circuits (not shown), and the dielectric layer 314 may include various connecting metal layers 333.

As also illustrated, the dielectric layers 314, 318 may be used to construct desired bonds between the ASIC wafer 312 and the CIS wafer 316, illustrated in FIG. 3 as hybrid bonds 354. A saw street 337 refers to a portion of the illustrated chip stack used to perform sawing or singulation activities.

Various active circuits 326 may be positioned in or on the backside surface of the CIS wafer 316. For example, a color filter array and microlens array may be included. The active circuits 326 may include or utilize a Tungsten shield 328, as an example of the light shield 128 of FIG. 1, and/or various other light shield and/or antireflective materials to facilitate image sensing operations, as well as trench isolation structures 353 for electrical and/or light isolation purposes. Metal layers 355 may be used to connect the active circuits 326 to the hybrid bonds 354, and thus to the ASIC chip 302.

Further in FIG. 3, and as described with respect to FIG. 1, as the light shield 328 is made of metal, the types of charge buildup referenced above may occur in the light shield 328. A ground contact 330 may be included that connects the light shield 328 to the second wafer 316. In some implementations, the connection may be made between the light shield 328 and the second wafer 316 using a via formed through an intervening dielectric 343 and doped layer 344.

Consequently, an electrostatic discharge path 352 exists through, as shown, intervening portions of the second wafer 316, the second dielectric layer 318, the first dielectric layer 314, and the first wafer 312, as well as included metal layers 355, hybrid bonds 354, and metal layers 333. In addition, other metal layers or metal elements, such as a die seal layer 132, may experience charge buildup. It therefore may be advantageous to provide an additional or alternative discharge path to provide a grounding connection.

For example, the chip stack of FIG. 3 includes an additional electrostatic discharge path 351, which provides a suitable path to ground. For example, the electrostatic discharge path 351 includes a first die seal 336 in the first dielectric layer 314, a second die seal 338 in the second dielectric layer 318, and a hybrid bond 340 that connects the first die seal 336 and the second die seal 338 at the bond line 310.

The hybrid bond 340 is illustrated in cross-section in the example of FIG. 3. As described with respect to FIG. 1, the hybrid bond may not be present in other cross sections of the chip stack 300, e.g., may represent a discrete or non-continuous hybrid bond that is positioned at desired intervals under the die seal layer 332.

The electrostatic discharge path 351 may include various other elements and aspects that facilitate sufficient electrostatic discharge, the same as or similar to elements described with respect to electrostatic discharge path 135 in FIG. 1. For example, a ground contact 342 may connect the die seal layer 332 to the second wafer 316. Similar to the ground contact 330, the ground contact 342 may be positioned within a via formed through an intervening dielectric 343 and doped layer 344. Further, a doped layer 348 may be provided with additional doping to facilitate conduction along the electrostatic discharge path 351. A similar doped layer 349 may be provided as part of the first die seal 336, and positioned near a border of the first dielectric layer 314 and the first wafer 312.

Further in FIG. 3, a shield connection 350 is illustrated, corresponding to the shield connection 150 of FIG. 1. The cross-section B-B′ of FIG. 2 illustrated in FIG. 4 shows the shield connection 350 may be added that electrically connects the light shield 128 and the die seal layer 132. Specifically, FIG. 4 illustrates shield connection 450 as a metal element or metal portion between the light shield 328 and the die seal layer 332.

FIGS. 5A-5D illustrate example operations for manufacturing a second example implementation of the chip stack of FIG. 1. In FIG. 5A, an ASIC wafer 512 has first dielectric layers 514 formed thereon, with metal layers 533 formed therein. A sensor wafer 516 has second dielectric layers 518 formed thereon, including SiN layers 539. The sensor wafer 516 in FIG. 5A includes a bulk portion 500.

A bond pad 524 is formed in a layer of the second dielectric layers 514. Active circuits 526 are formed in the wafer 516 and the second dielectric layer(s) 518, while a seal ring 531 and second die seal 538 are formed in the second dielectric layer(s) 518. First die seal 536 is formed in the dielectric layer(s) 514. Doped layer 549 is formed in the dielectric layer(s) 514 and wafer 512.

As illustrated in FIG. 5A, the sensor wafer 516 and second dielectric layers 518 are flipped for mounting onto the first dielectric layers 514, such that the second dielectric layers 518 are between the first dielectric layers 514 and the sensor wafer 516. Accordingly, interconnects (e.g., hybrid bonds) 540 and 554 may be joined, such as shown in FIG. 5B, thereby defining a bond line 510. Metal layers 555 may be included to connect the active circuits 526 to the hybrid bonds 554, and thus to the ASIC chip 502.

The sensor wafer 516 in FIG. 5A may then be thinned by removing the bulk portion 500, e.g., to a range of 3-6 microns, as shown in FIG. 5B. For example, various known thinning techniques may be used, such as coarse grinding, fine grinding, wet etching, and/or combinations thereof. In some examples, the ASIC wafer 512 may also be thinned (not shown separately in the simplified process flow of FIGS. 5A-5D).

In FIG. 5C, backside processing is performed, which includes forming a deep trench 546, which may be filled with an insulating material (e.g., Silicon Dioxide) and lined by a doped layer 547 (e.g., doped with Boron). For example, the deep trench 546 may be formed at the same time as deep trenches 560 (e.g., isolation trenches) of active circuits 526. As referenced with respect to FIG. 1 and deep trench 146/electrostatic discharge path 135, the deep trench 546 provides the doped layer 547 in proximity to the second die seal 538, which facilitates a conductivity (reduces a resistance) of the electrostatic discharge path 351 of FIGS. 3 and 4. Moreover, as shown in FIG. 5C, the deep trench 546 may be formed during backside processing of the sensor wafer 516 (as opposed to frontside processing that would need to occur prior to bonding), in an efficient manner that does not damage active circuits 526 or other elements of the chip stack.

A dielectric layer 543 (e.g., Silicon Dioxide) may then be formed, through which vias may be opened to provide a ground contact 530 to a Tungsten shield 528, and to provide a ground contact 542 to a die seal layer 532.

In FIG. 5D, an opening 522 may be etched to access the bond pad 524, and lined with passivation layer 525. As described herein, during plasma etching of the opening 522, charge buildup may occur, e.g., on the Tungsten shield 528 and the die seal layer 532. Discharge of such a charge buildup may be facilitated by the trench 546, in contact with the ground contact 542, the second die seal layer 538, the hybrid bond 540, and the first die seal 536. Discharge may also be facilitated by virtue of a shield connection between the Tungsten shield 528 and the die seal layer 532, analogous to the shield connection 150 of FIGS. 1 and 2, or the shield connection 350/450 of FIGS. 3 and 4, which is not shown separately in FIGS. 5A-5D.

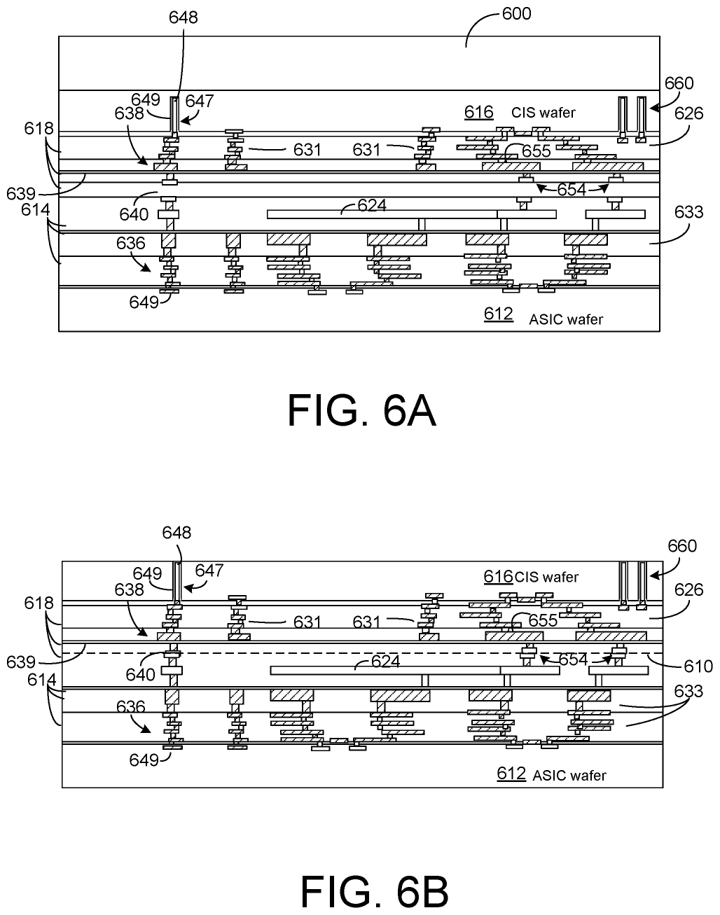

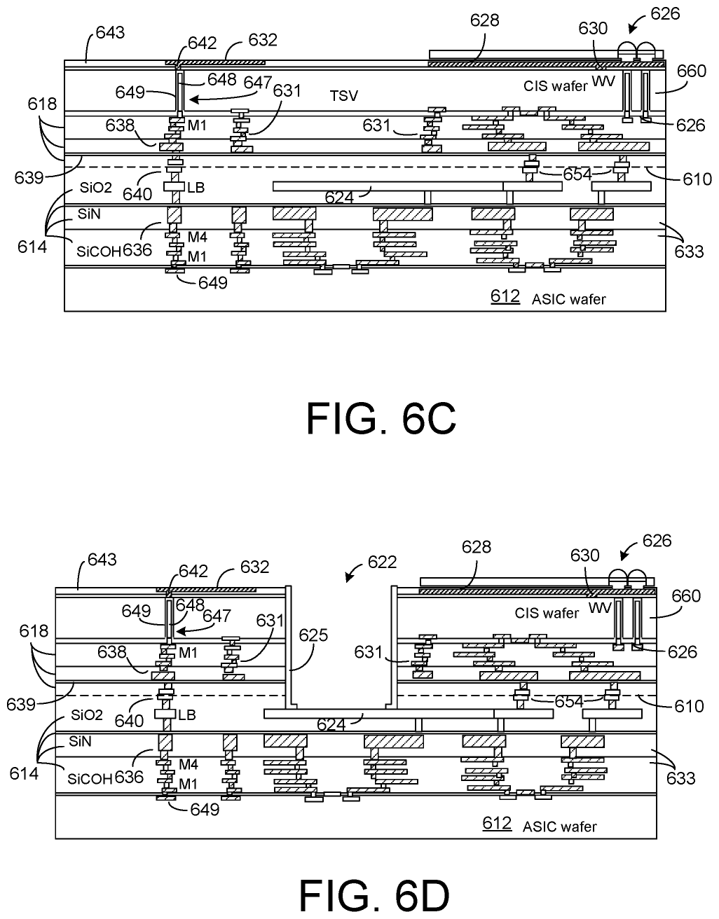

FIGS. 6A-6D illustrate example operations for manufacturing a third example implementation of the chip stack of FIG. 1. In FIG. 6A, an ASIC wafer 612 has first dielectric layers 614 formed thereon, with metal layers 633 formed therein. A sensor wafer 616 has second dielectric layers 618 formed thereon, including SiN layers 639. The sensor wafer 616 in FIG. 6A includes a bulk portion 600.

A bond pad 624 is formed in a layer of the second dielectric layers 614. Active circuits 626 are formed in the wafer 616 and the second dielectric layer(s) 618, while a seal ring 631 and second die seal 638 are formed in the second dielectric layer(s) 618. First die seal 636 is formed in the dielectric layer(s) 614.

As illustrated in FIG. 6A, the sensor wafer 616 and second dielectric layers 618 are flipped for mounting onto the first dielectric layers 614, such that the second dielectric layers 618 are between the first dielectric layers 614 and the sensor wafer 616. Accordingly, interconnects (e.g., hybrid bonds) 640 and 654 may be joined, such as shown in FIG. 6B, thereby defining a bond line 610. Metal layers 655 may be included to connect the active circuits 626 to the hybrid bonds 654, and thus to the ASIC chip 602.

The sensor wafer 616 in FIG. 6A may then be thinned by removing the bulk portion 600, e.g., to a range of 3-6 microns, as shown in FIG. 6B. The ASIC wafer 612 may also be thinned (not shown separately in the simplified process flow of FIGS. 6A-6D).

In FIG. 6C, backside processing is performed, which includes forming a conductive trench 647, which may be filled with a conductive material 648 (e.g., PolySilicon, or a metal) and lined by an insulating layer 649. For example, the conductive trench 647 may be formed at the same time as deep trenches 660 (e.g., isolation trenches) of active circuits 626. As referenced with respect to FIG. 1 and conductive trench 147/electrostatic discharge path 135, the conductive trench 647 facilitates a conductivity (reduces a resistance) of the electrostatic discharge path 351 of FIGS. 3 and 4. Moreover, as shown in FIG. 6C, the conductive trench 647 may be formed during backside processing of the sensor wafer 616 (as opposed to frontside processing that would need to occur prior to bonding), in an efficient manner that does not damage active circuits 626 or other elements of the chip stack.

A dielectric layer 643 (e.g., Silicon Dioxide) may then be formed, through which vias may be opened to provide a ground contact 630 to a Tungsten shield 628, and to provide a ground contact 642 to a die seal layer 632.

In FIG. 6D, an opening 622 may be etched to access the bond pad 624, and lined with passivation layer 625. As described herein, during plasma etching of the opening 622, charge buildup may occur, e.g., on the Tungsten shield 628 and the die seal layer 632. Discharge of such a charge buildup may be facilitated by the conductive trench 647, in contact with the ground contact 642, the second die seal 638, the hybrid bond 640, and the first die seal 636. Discharge may also be facilitated by virtue of a shield connection between the Tungsten shield 628 and the die seal layer 632, analogous to the shield connection 150 of FIGS. 1 and 2, or the shield connection 350/450 of FIGS. 3 and 4, which is not shown separately in FIGS. 5A-5D.

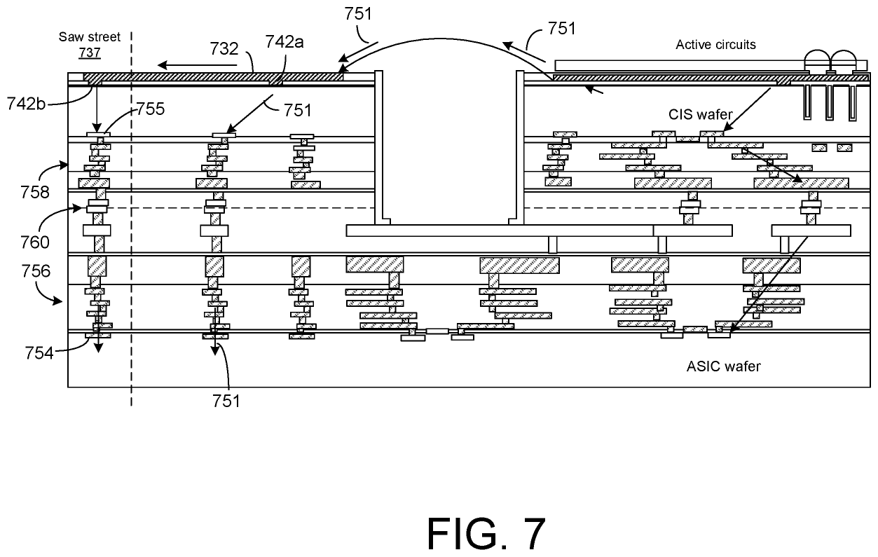

FIG. 7 illustrates a fourth example implementation of the chip stack of FIG. 1. In the example of FIG. 7, a saw street 737 may be leveraged for additional or alternative electrostatic discharge protection, prior to singulation operations.

For example, in FIG. 7, a die seal layer 732 may be extended to the saw street 737. Ground contacts 742a and 742b may be established through corresponding vias. Ground contact 742a may be formed in the chip, similar to ground contacts 342, 542, 642, and the ground contact 742b may be formed in the saw street 737, as shown. The ground contact 742b may sometimes be referred to as a “saw street ground contact.”

The saw street 737 may include a doped layer 754 as part of a first saw street die seal 756, a hybrid bond 760 (sometimes referred to as a “saw street hybrid bond”), and a second saw street die seal 758 that includes a doped layer 755. Consequently, a saw street electrostatic discharge path 751 is established that provides arcing prevention prior to singulation of the chip stack, using the techniques described herein.

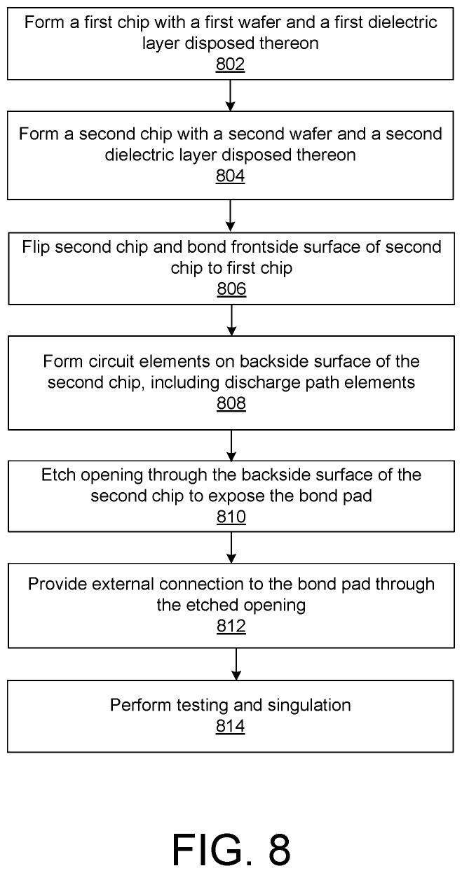

FIG. 8 is a flowchart illustrating example operations for manufacturing the chip stack of FIG. 1. In the example of FIG. 8, a first chip may be formed with a first wafer and a first dielectric layer disposed thereon (802). A second chip may be formed with a second wafer and a second dielectric layer disposed thereon (804).

The second chip may be flipped and a frontside surface of the second chip may be bonded to the first chip to define a bond line (806). Then, following thinning of the second wafer, circuit elements may be formed on a backside surface of the second chip.

The circuit elements include discharge path elements that form at least part of a discharge path. The discharge path elements may include one or more doped or conductive trench(es), a light shield, a die seal layer, and/or a shield connection between the light shield and the die seal layer (808).

An opening may be etched through the backside surface of the second chip to expose a bond pad (810). During etching, arcing caused by the presence of the plasma used for etching and associated electric field may be prevented by the discharge path formed by the discharge path elements. For example, the discharge path may include the described die seal structure, the light shield connection, the included hybrid bond, and any included trench structure(s).

An external connection to the bond pad may be provided through the etched opening (812), such as a wirebond connection. Testing and singulation may be performed (814).

It will be appreciated that the simplified example of FIG. 8 illustrates an example sequence of manufacturing operations, but that the various operations may occur in a different order than that shown and/or may have more or fewer operations than that shown. For example, depending on available testing and packaging options or preferences, singulation may occur prior to some or all testing operations.

The above-described implementations are for purposes of example, and associated descriptions and terminologies are non-limiting. For example, although the term chip is used herein with reference to singulated elements of a processed wafer, it will be appreciated that each such element may include, and/or may be referred to as, a die or semiconductor die. Thus, for example, in FIG. 1, the first chip 102 may be referred to as a first die, while the second chip 104 may be referred to as a second die. Other suitable terminology may be used, as well. Additionally, although the simplified chip stack 100 of FIG. 1 includes only the two chips 102, 104, it will be appreciated that some implementations of the chip stack 100 may include three or more stacked chips.

Additionally, although the above examples are primarily described with respect to image sensors and associated circuitry, other active circuits may be used, as well. For example, the first chip 102 of FIG. 1 may be Integrated Passive Chip (IPC), while the second chip 104 may be a Silicon PhotoMultiplier (SiPM) chip.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the embodiments.

What is claimed is:

1. A semiconductor device, comprising:
a first chip including a first wafer and a first dielectric layer disposed thereon;
a second chip including a second wafer and a second dielectric layer disposed thereon, the second chip being bonded to the first chip to define a bond line between the first dielectric layer and the second dielectric layer; and
an electrostatic discharge path including a die seal layer on the second wafer, a die seal ground contact for the die seal layer, a first die seal in the first dielectric layer, a second die seal in the second dielectric layer, and a hybrid bond connecting the first die seal and the second die seal through the bond line.

2. The semiconductor device of claim 1, further comprising:
a light shield;
an opening through a surface of the second chip extending through the second wafer and at least into the second dielectric layer; and
a shield connection electrically connecting the light shield and the die seal layer to thereby include the light shield in the electrostatic discharge path.

3. The semiconductor device of claim 1, further comprising:
a trench formed in the second wafer of the second chip and extending in a direction of the second die seal.

4. The semiconductor device of claim 3, wherein the trench includes a doped layer.

5. The semiconductor device of claim 3, wherein the trench includes a conductive material in contact with the die seal ground contact and with the second die seal.

6. The semiconductor device of claim 1, further comprising:
a saw street electrostatic discharge path formed in a saw street and including a saw street ground contact connected to the die seal layer, a first saw street die seal in the first dielectric layer, a second saw street die seal in the second dielectric layer, and a saw street hybrid bond connecting the first saw street die seal and the second saw street die seal through the bond line.

7. The semiconductor device of claim 1, wherein the first die seal includes a first doped layer in the first wafer, and the second die seal includes a second doped layer in the second wafer.

8. The semiconductor device of claim 1, further comprising:
a color filter array (CFA) and microlens array disposed on a surface of the second wafer opposite the second dielectric layer;
a light shield disposed on the second wafer; and
a light shield ground contact in contact with the second wafer.

9. The semiconductor device of claim 1, wherein the hybrid bond includes a copper-copper hybrid bond.

10. The semiconductor device of claim 1, wherein the second chip includes optical sensor circuitry and the first chip includes circuit chip circuitry configured to operate or receive an output of the optical sensor circuitry.

11. A semiconductor device, comprising:
a first chip including a first wafer and a first dielectric layer disposed thereon;
a second chip including a second wafer and a second dielectric layer disposed thereon, the second chip having a backside surface and a frontside surface opposed to the backside surface, the second chip being bonded to the first chip at the frontside surface to define a bond line between the first dielectric layer and the second dielectric layer;
a die seal layer on the backside surface;
a first die seal in the first dielectric layer;
a second die seal in the second dielectric layer;
a hybrid bond connecting the first die seal to the second die seal; and
a light shield on the backside surface being electrically connected to the die seal layer.

12. The semiconductor device of claim 11, further comprising:
an opening through the backside surface of the second chip and extending at least into the second dielectric layer; and
a shield connection electrically connecting the light shield and the die seal layer.

13. The semiconductor device of claim 11, further comprising:
a trench formed in the backside surface of the second chip and extending in a direction of the second die seal.

14. The semiconductor device of claim 13, wherein the trench includes a doped layer.

15. The semiconductor device of claim 13, wherein the trench includes a conductive material in contact with the die seal layer and the second die seal.

16. The semiconductor device of claim 11, further comprising:
a saw street ground contact connected to the die seal layer;
a first saw street die seal in the first dielectric layer;
a second saw street die seal in the second dielectric layer; and
a saw street hybrid bond connecting the first saw street die seal and the second saw street die seal through the bond line.

17. The semiconductor device of claim 11, further comprising a die seal ground contact in contact with the second wafer.

18. A method of making a semiconductor device, comprising:
forming a first chip including a first wafer and a first dielectric layer disposed thereon, the first chip including a first die seal;
forming a second chip including a second wafer and a second dielectric layer disposed thereon, the second chip having a backside surface and a frontside surface opposed to the backside surface, the second chip including a second die seal;
bonding the second chip to the first chip at the frontside surface to define a bond line between the first dielectric layer and the second dielectric layer, including a hybrid bond connecting the first die seal and the second die seal; and
forming a die seal layer on the backside surface having a die seal ground contact in contact with the second wafer to define an electrostatic discharge path that includes the die seal layer, the die seal ground contact, the first die seal, the second die seal, and the hybrid bond.

19. The method of claim 18, further comprising:
forming a light shield on the backside surface of the second wafer;
connecting the light shield to the die seal layer to thereby include the light shield in the electrostatic discharge path; and
forming an opening through the backside surface of the second chip that extends at least into the second dielectric layer.

20. The method of claim 18, further comprising:
forming a trench in the backside surface of the second chip and extending in a direction of the second die seal.
